(19) United States
(12) Patent Application Publication
(10) Pub. No.: US 2014/0346468 A1
(43) Pub. Date: Nov. 27, 2014

(54) ORGANIC LIGHT EMITTING DISPLAY DEVICE HAVING A CHANNEL IN PIXEL DEFINING LAYER

(71) Applicant: SAMSUNG DISPLAY CO., LTD., Yongin-si (KR)

(72) Inventor: Jang-Sub KIM, Suwon-si (KR)

(73) Assignee: SAMSUNG DISPLAY CO., LTD., Yongin-si (KR)

(21) Appl. No.: 14/135,373

(22) Filed: Dec. 19, 2013

(30) Foreign Application Priority Data
May 27, 2013 (KR) 10-2013-0059751

(51) Int. Cl. H01L 27/32; H01L 51/56

(52) U.S. Cl. CPC H01L 27/32; H01L 51/56
USPC 257/40; 438/34

(57) ABSTRACT

A display device with channels formed in the pixel defining layer is presented. The display device includes a substrate, a pixel defining layer disposed on the substrate to define pixel areas, and channels extending between different pixel areas to allow deposited material to move/flow from one area to another and achieve a substantially even distribution. The pixel area includes a first electrode, an emission layer on the first electrodes, and a second electrode on the emission layer. A method for making such display device is also presented.

### CROSS-REFERENCE TO RELATED APPLICATION

This application claims priority to and the benefit of Korean Patent Application No. 10-2013-0059751 filed on May 27, 2013 with the Korean Intellectual Property Office, the disclosure of which is incorporated herein by reference in its entirety.

### BACKGROUND

1. Field

The present disclosure relates to an organic light emitting display device having an improved pixel defining layer structure and a method for manufacturing thereof.

2. Description of Related Art

An organic light emitting display device is a self-emission display device as the organic light emitting diode emits light to display an image. Today, organic light emitting display devices receive much attention as a possible next-generation mainstream display device. Organic light emitting display devices offer a number of advantages such as low power consumption, high luminance, rapid response speed, and the like.

In the organic light emitting display device, a basic unit for displaying an image is often referred to as “a pixel.” A pixel includes a first electrode and a second electrode, and an organic layer disposed between the first electrode and the second electrode. The organic layer generally includes an emission layer that is deposited.

A pixel defining layer is sometimes provided in an organic light emitting display device to separate regions of the pixels from each other in the organic light emitting display device. The pixel defining layer may be in a mesh form to define the pixel areas. Pixel areas are where pixels are formed. That is, the first electrodes are separately formed, the pixel defining layer is formed to separate the first electrodes into pixel areas, and a variety of materials (e.g., organic materials) are deposited on at least one first electrode in one of the pixel areas. During this process, the deposited materials would ideally be uniformly disposed in the respective pixel areas.

When a material is deposited to form a layer in the pixel area, the material is usually also deposited on the pixel defining layer around the pixel area. The pixel defining layer is higher than the first electrode, causing some of the material to flow from the top of the pixel defining layer to a pixel area that is lower as the deposited material is usually a fluid. If the material is not uniformly distributed in across the different pixel areas during this flow of the material, varying amounts of material may be deposited in different pixel areas. A non-uniform deposition of the material causes non-uniform light emission in each pixel may not be uniform.

### SUMMARY OF THE DISCLOSURE

Embodiments of the present inventive concept provide an organic light emitting display device with an pixel defining layer structure to distribute organic materials uniformly in respective pixel areas when materials (including organic materials) are deposited on the pixel areas to form a pixel, and a method of manufacturing the organic light emitting display device.

Embodiments of the present inventive concept provide an organic light emitting display device, wherein a channel is formed in a pixel defining layer, and a method of forming the channel in the pixel defining layer.

In one aspect, the inventive concept pertains to a display device, comprising a substrate; a pixel defining layer defining pixel areas disposed on the substrate; wherein each of the pixel areas comprises, a first electrode; an emission layer on the first electrodes; and a second electrode on the emission layer, and wherein the pixel defining layer has a channel extending between at least two pixel areas.

The pixel defining layer may comprise a floor having a slope in the channel along a longitudinal direction of the channel.

An average angle of the slope may be in a range of about 10° to about 45° relative to a surface of the first electrode.

The channel may extend in at least one direction.

The floor may have a peak in the channel and the slopes extend down from the peak in different directions from the peak.

The floor may have a peak at one end and a lowest point at the other end along a longitudinal direction of the channel.

A cross section of the floor cut along a direction perpendicular to the longitudinal direction of the channel may have one of a U-shape, an inverted triangle shape, and a quadrangular shape.

At least one of the pixel areas may further comprise at least one of a hole injection layer and a hole transport layer between the first electrode and the emission layer.

Each of the pixel areas may further comprise a hole injection layer on the first electrode; a primer layer on the hole injection layer; and a hole transport layer on the primer layer.

The pixel may further comprise at least one of an electron transport layer and an electron injection layer between the emission and the second electrode.

In another aspect, the inventive concept pertains to a manufacturing method of an organic light emitting display device, comprising: forming a plurality of first electrodes on a substrate; forming a pixel defining layer between the first electrodes; forming an emission layer on the first electrode; and forming a second electrode on the emission layer, wherein the forming of a pixel defining layer includes forming a channel that is configured to allow a fluid material to flow between the first electrodes.

The forming of a pixel defining layer may include forming a pattern using a photoresist and a mask, and the mask has a channel forming unit and the channel forming unit is formed to change light transmission along a longitudinal direction.

The method may further comprises coating at least one of a material for forming a hole injection layer and a material for forming a hole transport layer on the first electrode and the pixel defining layer before the forming of an emission layer and after the forming of the pixel defining layer.

The coating of at least one material for forming a hole injection layer and a material for forming a hole transport layer may entail using an ink printing method.

An ink printing method may be used in the forming of an emission layer.

The slope in the channel floor may be configured to move a liquid deposited on one part of the substrate to another part.

The floor of the channel may be at the same level as or higher than the first electrode.

In the organic light emitting display device according to embodiments of the present inventive concept, a channel is formed in a pixel defining layer, so that when a variety of organic materials are deposited during a manufacturing process of the organic light emitting display device, the organic materials may be uniformly disposed in each pixel. Accordingly, emission uniformity may increase in the organic light emitting display device.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram schematically illustrating a structure of an organic light emitting display device according to an embodiment of the present inventive concept.

FIG. 2 is a perspective view schematically illustrating structures of a first electrode and a pixel defining layer in an organic light emitting display device according to an embodiment of the present inventive concept.

FIG. 3 is a top view of the first electrode and the pixel defining layer on a substrate illustrated in FIG. 2.

FIGS. 4A to 4D are cross-sectional views cut along a longitudinal direction of a channel, as examples of a structure of the channel formed in a pixel defining layer.

FIGS. 5A to 5C are cross-sectional views cut along a width direction of a channel, as examples of a structure of the channel formed in a pixel defining layer.

FIG. 6 illustrates an example of a structure of an organic light emitting display device according to an embodiment of the present inventive concept in more detail.

FIG. 7 illustrates a structure of a mask according to an embodiment of the present inventive concept.

### DETAILED DESCRIPTION

Hereinafter, the present inventive concept will be described in detail with reference to the embodiments shown in the accompanying drawings. However, the scope of the present inventive concept is not limited to the following description or the embodiments shown in the drawings. The accompanying drawings are only for illustration of embodiments selected from among the various embodiments of the present inventive concept, and thus, should not limit the scope of the present inventive concept.

In the drawings, certain elements or shapes may be simplified or exaggerated to better illustrate the disclosure, and other elements present in an actual product may also be omitted. Thus, the drawings are intended to facilitate the understanding of the disclosure.

Throughout the disclosure, like reference numerals refer to like elements throughout the various figures and embodiments of the present inventive concept. In addition, when a layer or element is referred to as being “on” another layer or element, the layer or element may be directly on the other layer or element, or one or more intervening layers or elements may be interposed therebetween.

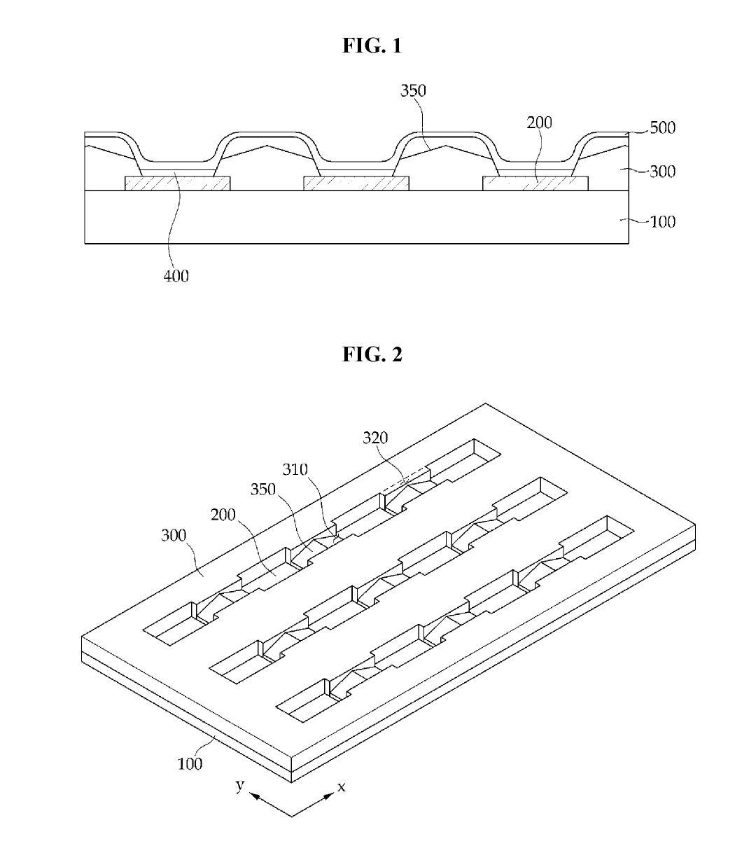

As illustrated in FIG. 1, an organic light emitting display device according to an embodiment of the present inventive concept may include a substrate 100, a plurality of first electrodes 200 on the substrate 100, a pixel defining layer 300 located between the first electrodes 200 and outlining pixel areas, an emission layer 400 on the first electrode 200, and a second electrode 500 on the emission layer 400. Further, the pixel defining layer 300 has a channel 310 disposed between the pixel areas, e.g. pixel areas adjacent to each other. The the pixel defining layer 300 has a floor 350. In the embodiment of FIG. 1, the floor 350 has a highest point approximately midway between the two pixel areas that the channel 310 connects, with two surfaces sloping downward toward the pixel areas. Although the downward-sloping portions are shown to be substantially symmetric with respect to the highest point, this is not a limitation of the disclosure.

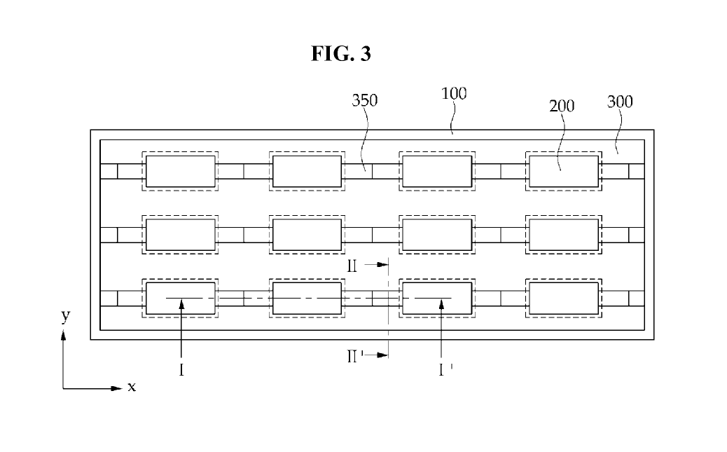

FIGS. 2 and 3 illustrate structures of a first electrode 200 and a pixel defining layer 300 on a substrate 100 in an organic light emitting display device according to an embodiment of the present disclosure.

FIG. 2 is a perspective view illustrating structures of a substrate 100, a first electrode 200 on the substrate 100, and a pixel defining layer 300 separating the first electrodes 200. As illustrated in FIG. 2, a channel 310 is formed in the pixel defining layer 300. The pixel defining layer 300 defines the pixel areas by being disposed between the first electrodes adjacent to each other, for example by creating a “wall.” As mentioned before, the adjacent pixel areas may be connected to each other by the channel 310 in the pixel defining layer 300.

As illustrated in FIG. 2, the channel 310 is open, the pixel defining layer 300 has side walls 320 on two sides of a pixel area and has the channel 310. A space defined by the side walls 320 and the floor 350 is herein referred to as the channel 310. The channel 310 may be formed as a shape of furrow or valley. In some embodiments, the floor 350 may have a flat surface. In other embodiments, such as the one illustrated in FIG. 2, the floor 350 may be sloped downward from a peak that is positioned between two pixel areas, such that a cross section of the channel “sliced” from one pixel area to the other includes a triangular shape.

FIG. 3 is a top view of the first electrode 200 and the pixel defining layer 300.

Referring to FIGS. 2 and 3, the channel 310 is formed connecting first electrodes 200 arranged in one direction. More specifically, FIGS. 2 and 3 illustrate embodiments in which the channels 310 extend along and are arranged in an X-direction. In other embodiments, the channels 310 may also be formed in a Y-direction or a diagonal direction.

The channel 310 is formed in the pixel defining layer 300 to connect at least two pixel areas, and the channels 310 may be formed in a predetermined direction. FIGS. 2 and 3 illustrate the channels which are formed in an X-axis direction. Here, the direction of formation of the channels 310 may be referred to as a direction of length of the channels or a direction of extension of the channels. In FIGS. 2 and 3, the length direction of the channels corresponds to an X-axis direction. The Y-axis direction corresponds to a direction of widths of the channels.

The channel 310 connects the pixel areas adjacent to each other along a single direction. In other words, a channel 310 connects the two pixel areas (each pixel area including a first electrode 200) that are positioned on both ends of the channel 310, along the X-axis direction as illustrated in FIGS. 2 and 3.

Although not explicitly shown in the Figures, the channel 310 may be formed in multiple directions so as to connect three or four pixel areas to each other.

As illustrated in FIG. 2, the floor 350 may have a peak having different slopes along the length direction (the X-axis direction) of the channel 310. The peak in the channel 310 is at the same height as or lower than the upper surface of the pixel defining layer 300 and/or the side wall 320.

The pixel defining layer 300 is formed in a corner part of the first electrode 200 so as to separate respective pixel areas. By forming the pixel defining layer 300, a pixel area is defined on the first electrode 200. After the pixel defining layer 300 is formed, in order to form a pixel, a variety of materials, in particular various organic materials are deposited in the pixel area of the first electrode 200. During the series of depositions, it is desired for each to be uniformly disposed in each pixel area. However, the materials may not be uniformly distributed in each pixel area.

During the deposition processes, the material may also land on the parts of the pixel defining layer 300 other than the pixel areas, and this material may move or flow down to a nearby pixel area during a drying process, etc. When the materials flow to the pixel and are not uniformly distributed in the respective pixel areas, non-uniformity of material occurs in the pixel areas. When such non-uniformity of material occurs, emission from each pixel may be non-uniform. In the present disclosure, in order to suppress the non-uniformity of material, the channel 310 is formed in the pixel defining layer 300, and the floor 350 may have slopes as described above. Where there is a slope on the channel floor 350, the materials for forming a pixel coated on the pixel defining layer 300 may move/flow to a pixel area along the channel more efficiently. Hence, the channel 310 and the floor 350 contributes to an even material distribution over the pixel areas.

The floor 350 may have a peak (h) to form the slopes, and thus the materials may be distributed on the peak (h). The dimensions of the channels 310 and the slope(s) of the floor 350 may be chosen according to various parameters of the material to be deposited, such as the amount and the viscosity of the material.

When the angle of the slopes in the floor 350 of the channel 310 is too small, the materials may not move/flow efficiently. Therefore, the steeper the slopes, the faster the materials will move. Since there is a limit on a height of the pixel defining layer 300 and the length of the channel 310, the angle of slopes may be limited to a range. For example, an average angle of the slope may be in the range of 10° to 45° with respect to a surface of the first electrode 200. However, the slope cannot be generally limited to this range, as the range will vary from embodiment to embodiment. For the channel 310 to function, the slope of the floor 350 may vary with a size of the pixel defining layer 300. Bends may be formed in parts of the floor 350, such that the angle changes along the slope.

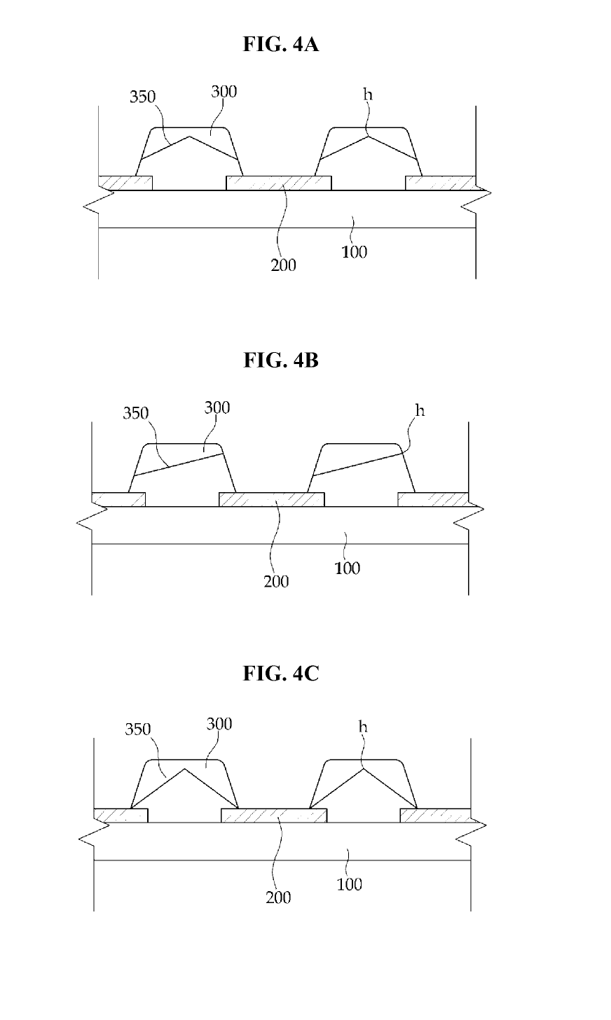

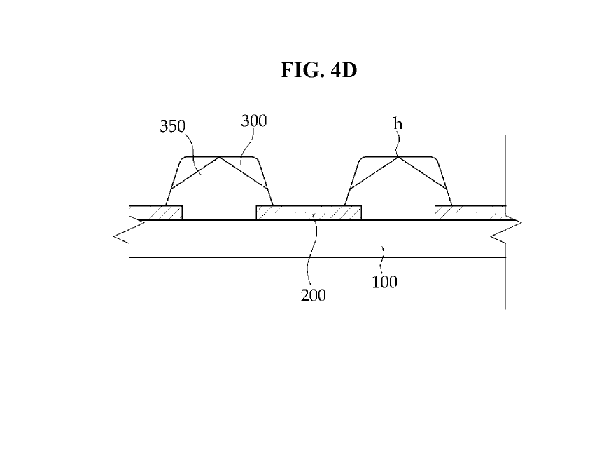

FIG. 4A is a cross-sectional view cut away along dotted line I-I′ in FIG. 3.

Further, FIGS. 4B to 4D show other embodiments of a structure containing a first electrode 200 and a pixel defining layer 300 cut along a longitudinal direction (an X-axis direction) of the channel 310.

In FIGS. 4A to 4D, a portion having reference numeral “350” represents a lower part in the channel 310.

As illustrated in FIG. 4, the lower part 350 in the channel 310 may have the peak and the lowest point in height on the basis of a top surface of the first electrode 200. In the drawing, the peak of the floor 350 corresponds to a part shown as “h” and the lowest point is close to the pixel area.

The difference in height between the peak (h) and the lowest point in the floor 350 of the channel 310 may be in the range of 0.2 μm to 5 μm. The difference in height may vary depending on a size and a height of the pixel defining layer 300. When the pixel defining layer 300 is very thin, the difference may be smaller than the above range, and when the pixel defining layer 300 is very thick, the difference may be larger than the above range.

Although the channel 310 is formed in the pixel defining layer 300, the pixel defining layer 300 plays a role in separating and insulating the first electrodes 200 from each other. Therefore, the floor 350 in the channel 310 has a predetermined minimum height. The height is measured from the top of the first electrode 200. In case where the height of the floor 350 in the channel 310 is not different from the height of the first electrode 200 because the channel 310 is formed deep, electric current may flow between the first electrodes 200. In this regard, the peak (h) of the floor 350 is required to have a height greater than a predetermined minimum height. Meanwhile, the height of the peak of the floor 350 is limited to a thickness of the pixel defining layer 300. In view of the foregoing, the highest point (h) may be formed to be higher than a top surface of the first electrode 200 by about 0.3 μm to 5 μm.

Further, the lowest point of the lower part 350 in the channel 310 may have the same height as the top surface of the first electrode 200, or the lowest point may be higher in the range of 0.3 μm to a few micrometers than the first electrode 200.

FIGS. 4A to 4D illustrate the lower part 350 in the channel 310.

According to an embodiment of the present disclosure, as illustrated in FIG. 4A, the floor 350 of the channel 310 has a peak (h), and may have different slopes along a longitudinal direction of the channel on the basis of the peak (h).

According to another embodiment, as illustrated in FIG. 4B, the floor 350 in the channel 310 has the lowest point at one end (at the left pixel area) and the highest point (h) at the other end (at the right pixel area) along a longitudinal direction of the channel 310. In this embodiment, there is no peak midway between the adjacent pixel areas as in the embodiment of FIG. 4A and there may only be one slope extending in one direction.

According to yet another embodiment, as illustrated in FIG. 4C, the lowest point of the floor 350 in the channel 310 may coincide with a surface of the first electrode 200.

According to yet another embodiment, as illustrated in FIG. 4D, the level of the peak of the floor 350 of the channel 310 may coincide with the top surface of the pixel defining layer 300.

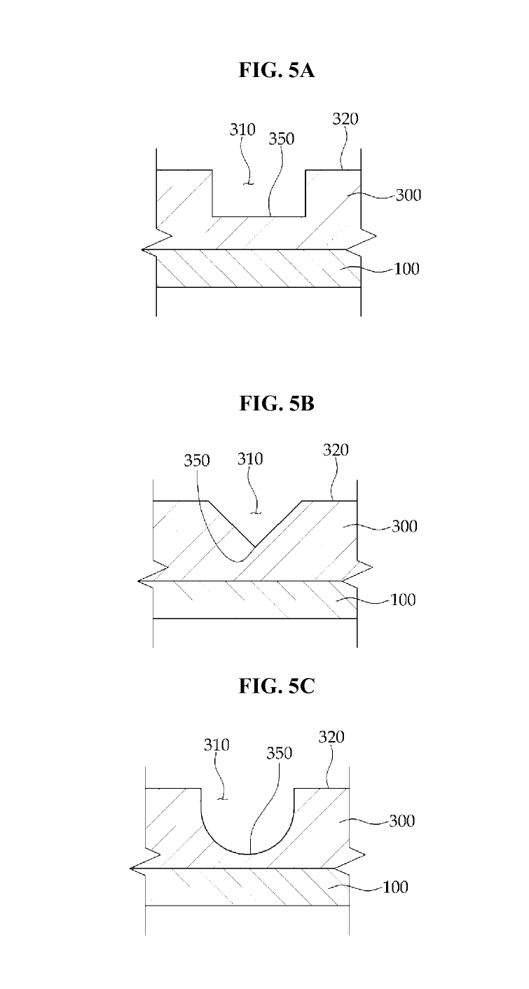

FIG. 5A is a cross-sectional view cut away along dotted line II-II′ in FIG. 3. Further, FIGS. 5B and 5C illustrate cross-sectional views of other examples of a structure of a channel 310 cut along a width direction of the channel 310. As illustrated in FIGS. 5A to 5C, a cross-section of the channel 310, which is cut along a direction (the width direction) perpendicular to a longitudinal direction of the channel 310 may have a shape of quadrangle (FIG. 5A) or inverted triangle (FIG. 5B), or a U-lettered shape (FIG. 5C).

As illustrated in FIGS. 2 and 5A to 5C, the pixel defining layer 300 may have sidewalls 320 along the sides of the channel 310 in the longitudinal direction of the channel 310. According to an embodiment of the present disclosure, the width between the sidewalls 320 may range from 2 μm to 10 μm, inclusive.

According to an embodiment of the present disclosure, at least one of a hole injection layer and a hole transport layer may be disposed between the first electrode 200 and the emission layer 400. Both the hole injection layer and the hole transport layer may also be disposed between the first electrode 200 and the emission layer 400.

In some cases, the hole injection layer and the hole transport layer are different from each other in terms of polarity, and when the hole injection layer is formed on the first electrode 200, and thereafter the hole transport layer is formed, a material for forming the hole transport layer may not be uniformly coated on the hole injection layer. In such a case, a primer may be coated on the hole injection layer. The primer may be selected from materials that have hole transport properties satisfactory enough not to block hole transport and improve interface properties between the hole injection layer and the hole transport layer. In the case of using such a primer, the material for forming the hole transport layer may be uniformly coated on the hole injection layer by improving the interface properties between the hole injection layer and the hole transport layer. Further, no problem occurs in emission properties due to the primer.

In case where a pixel is formed by deposition of a variety of materials, one material may not be smoothly coated on another material layer due to differences in properties between the respective materials. However, with the inventive concept of the disclosure, the material may uniformly disperse itself by flowing through the channels 310.

The channel 310 according to an embodiment of the present disclosure may be usefully applied to ink to be uniformly dispersed throughout a pixel area in particular when pixel-forming materials are deposited by a printing method.

An embodiment of the present disclosure also provides a manufacturing method of an organic light emitting display device having the channel 310. The manufacturing method may include forming a plurality of first electrodes 200 on a substrate 100, forming a pixel defining layer 300 between the first electrodes 200, forming an emission layer 400 on the first electrode 200, and forming a second electrode 500 on the emission layer 400. The forming of the pixel defining layer 300 includes forming the channel 310 having a cross section having a shape of concave groove and connecting the first electrodes 200 adjacent to each other.

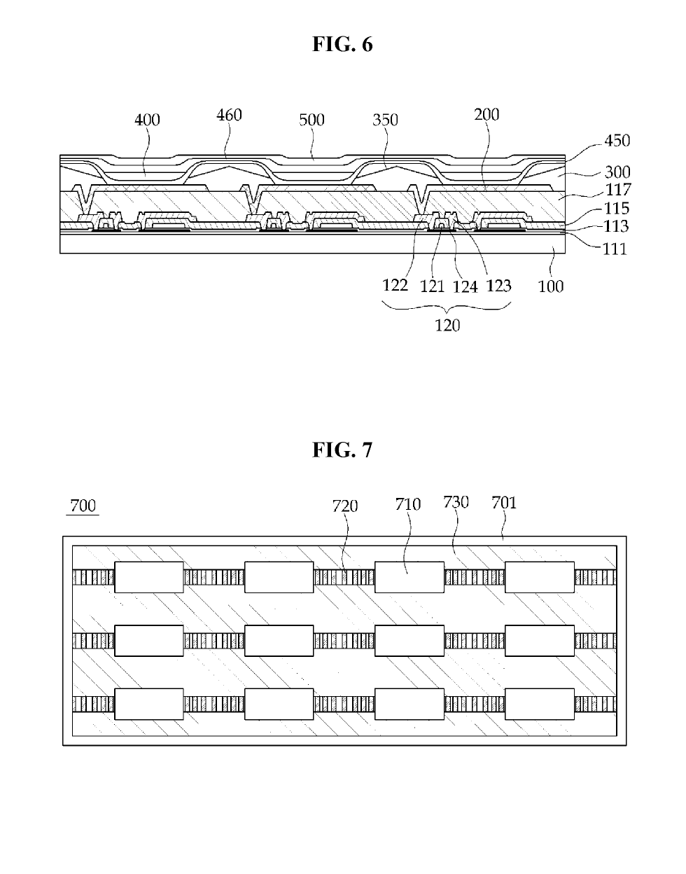

FIG. 6 illustrates a structure of an organic light emitting display device according to an embodiment of the present disclosure in more detail. Hereinafter, referring to FIG. 6, a manufacturing method of the organic light emitting display device according to an embodiment will be described.

In the organic light emitting display device illustrated in FIG. 6, glass or polymer plastic conventionally used in organic light emitting display devices may be used as a substrate 100. The substrate 100 may be transparent or not. The substrate 100 may be appropriately selected by a person skilled in the art as necessary.

A first electrode 200 is formed on the substrate 100, and a plurality of thin film transistors 120 may be formed on the substrate 100 before the first electrode 200 is formed. The thin film transistor 120 includes a gate electrode 121, a drain electrode 122, a source electrode 123, and a semiconductor layer 124. A gate insulating layer 113 and interlayer insulating layer 115 are also provided in the thin film transistors 120. The structure of the thin film transistor 120 is not limited to the structure shown in FIG. 6, and may be configured in different forms. Further, the semiconductor layer 124 may be formed of an organic material or an inorganic material. A buffer layer 111 formed, for example, of silicon oxide, silicon nitride, or the like may be further provided between the thin film transistor 120 and the substrate 100.

The first electrode 200, the emission layer 400, and the second electrode 500 are sequentially formed on the thin film transistors 120.

The first electrode 200 is electrically coupled to the underlying thin film transistor 120 located below the first electrode 200, and if a planarization layer 117 covering the thin film transistor 120 is provided, the first electrode 200 is located on the planarization layer 117. Here, the first electrode 200 is electrically coupled to the thin film transistor 120 through a contact hole provided in the planarization layer 117.

FIG. 6 illustrates that the first electrode 200 serves as an anode. The first electrode 200 may be a transparent or reflective electrode. When the first electrode 200 is a transparent electrode, it may be formed of indium tin oxide (ITO), indium zinc oxide (IZO), zinc oxide (ZnO), or indium(III) oxide (In₂O₃), and when the first electrode 200 is a reflective electrode, it may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), or a combination thereof, and a layer formed of ITO, IZO, ZnO, or In₂O₃ on the reflective layer.

Between the first electrodes 200, a pixel defining layer 300 may be provided. The pixel defining layer 300 is formed of an insulating material and separates the first electrodes 200 into corresponding pixel units. For example, the pixel defining layer 300 is located at the edges of the first electrodes 200 to separate the first electrodes 200 into corresponding pixel units, thereby defining pixel areas. That is, the pixel defining layer 300 may cover the edges of the first electrodes 200. Besides defining a pixel area, the pixel defining layer 300 widens a space between the edge of the first electrode 200 and the second electrode 400 so as to prevent electric field from being concentrated at the edge of the first electrode 200, thereby preventing a short circuit from occurring between the first electrode 200 and the second electrode 400.

The forming of the pixel defining layer 300 includes forming a pattern using photoresist. The photoresist may be applied by being appropriately selected between a positive type whose light-exposed portion is etched and a negative type whose non-light-exposed portion is etched.

In detail, the first electrode 200 is formed on the substrate 100, a material for forming a pixel defining layer is deposited on the front surface of the substrate 100 including the first electrode 200, and then the material for forming a pixel defining layer is patterned, thereby forming the pixel defining layer. The photoresist is used in the process of patterning the material for forming a pixel defining layer. By the patterning, the material for forming a pixel defining layer in some areas of an upper part of the first electrode 200 is removed to form an opening on the first electrode 200. The opening on the first electrode 200 corresponds to a pixel area.

In the patterning of the material for forming a pixel defining layer, a channel 310 is formed by patterning an area where the channel 310 will be formed.

The forming of a pattern may include exposure to light using a mask.

In other words, the forming of the pixel defining layer may include forming a pattern using photoresist and mask, the mask has a channel-forming unit, and the channel-forming unit may be formed to change light transmission along a longitudinal direction.

FIG. 7 shows an example of the mask 700.

The mask 700 includes a supporting substrate 701, and a light blocking portion 730 and a light transmission portion 710 on the supporting substrate 701. In the mask 700 illustrated in FIG. 7, the light transmission portion 710 corresponds to the opening on the first electrode 200. The mask 700 may be applied in the case where the positive photoresist is used.

The mask 700 has a channel-forming unit 720 between the light transmission portions 710, and the channel-forming unit 720 is configured to change light transmission along a longitudinal direction of a channel. As a result, in the forming of a pattern, light exposure may vary depending on the longitudinal direction of the channel-forming unit of the mask.

The mask 700 illustrated in FIG. 7 is an example of providing a slit in the channel-forming unit 720 so as to change light transmission in the channel-forming unit 720 along the longitudinal direction of a channel. A portion marked with diagonal lines in the channel-forming unit 720 corresponds to the slit, and the mask 700 illustrated in FIG. 7 changes light transmission by changing distances between the slits.

According to another embodiment of the present disclosure, the light transmission may vary along a longitudinal direction of a channel in the channel-forming unit 720 of the mask 700. For example, instead of providing a slit, there may be a method in which the channel-forming unit 720 is coated with a light absorbing material, and a concentration of the coated light absorbing material varies along the longitudinal direction of a channel.

According to an embodiment of the present disclosure, the channel-forming unit 720 may be configured to change the light transmission as it goes in two directions on the basis of a portion of the longitudinal direction of a channel in a part corresponding to the channel-forming unit 720 of the mask 700.

According to another embodiment of the present disclosure, the channel-forming unit 720 may be configured to change the light transmission gradually from one end of the longitudinal direction of a channel to the other end thereof in the channel-forming unit 720 of the mask 700.

According to an embodiment of the present disclosure, in the forming of the pixel defining layer 300, a bank having a width ranging from 2 μm to 10 μm may be formed on both sides of the longitudinal direction of a channel.

An emission layer 400 is located at an opening of the first electrode 200 separated by the pixel defining layer 300. The emission layer 400 may include a red emission layer, a green emission layer, and a blue emission layer. The emission layer 400 may further include a white emission layer. Further, the emission layer 400 may consist of the white emission layer only. In the case where the emission layer 400 may consist of white emission layer only, a color filter layer may be further provided.

The emission layer 400 may be formed in various methods such as deposition method, printing method, or transfer method using a donor film for transfer.

Meanwhile, at least one or more of a hole injection layer and a hole transport layer may be further provided between the first electrode 200 and the emission layer 400. The hole injection layer and the hole transport layer may be formed by vacuum evaporation using a mask or a printing method.

According to an embodiment of the present disclosure, before the forming of the emission layer 400 and after the forming of the pixel defining layer 300, depositing at least one of a material for forming the hole injection layer and a material for forming the hole transport layer on the front surface of the first electrode 200 and the pixel defining layer 300 may be further included. In this case, the printing method using ink may be applied to deposit at least one of the materials for forming the hole injection layer and the material for forming the hole transport layer,

FIG. 6 illustrates that a hole injection layer 450 is formed on the first electrode 200 and the pixel defining layer 300. For example, the hole injection layer 450 may be formed on the entire first electrode 200 and the entire pixel defining layer 300.

Although not illustrated in the drawing, a hole transport layer may be formed on an upper part of the first electrode 200 after a primer may be deposited on the hole injection layer 450.

In the case where the printing method is used to form the emission layer, the hole injection layer, or the hole transport layer, the channel 310 formed in the pixel defining layer 300 as described above is useful to achieve uniform ink distribution. In other words, when applying the printing method, some parts may not be smoothly and evenly deposited due to differences in properties between materials, and the ink may not be uniformly distributed among respective pixel areas. However, in the case of forming the channel 310 in the pixel defining layer 300, the ink flows into the pixel areas along the channel, and since the slope is formed in the channel, it is advantageous to distribute the ink among the pixel areas.

A second electrode 500 is located on the emission layer 400 and the pixel defining layer 300. The second electrode 500 may be formed of a material generally used in the art. The second electrode 500 may be a transparent electrode or reflective electrode. When the second electrode 500 is a transparent electrode, it may include a layer formed of lithium (Li), calcium (Ca), lithium fluoride/calcium (LiF/Ca), lithium fluoride/aluminum (LiF/Al,), Al, Mg, or a compound/combination thereof, and a layer formed thereon, which consists of a transparent electrode-forming material such as ITO, IZO, ZnO, In₂O₃, or the like. When the second electrode 500 is a reflective electrode, it may be provided by depositing lithium (Li), calcium (Ca), lithium fluoride/calcium (LiF/Ca), lithium fluoride/aluminum (LiF/Al,), Al, Mg, or a compound/combination thereof.

At least one of a hole injection layer or a hole transport layer may be located between the emission layer 400 and the second electrode 500. The hole injection layer and the hole transport layer may be formed by a deposition method, a printing method, or any other suitable known method. FIG. 6 illustrates an electron injection layer 460 formed between the emission layer 400 and the second electrode 500.

Although not illustrated in the drawing, various kinds of protection layer or sealing layer may be located on the second electrode 500.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A display device, comprising:
a substrate; and
a pixel defining layer defining pixel areas disposed on the substrate;
wherein each of the pixel areas comprises:
a first electrode;
an emission layer on the first electrode; and
a second electrode on the emission layer, and
wherein the pixel defining layer has a channel extending between at least two of the pixel areas.

2. The display device of claim 1, wherein the pixel defining layer comprises a floor having a slope in the channel along a longitudinal direction of the channel.

3. The display device of claim 2, wherein an average angle of the slope is in the range of about 10° to about 45° relative to a surface of the first electrode.

4. The display device of claim 1, wherein the channel extends in at least one direction.

5. The display device of claim 2, wherein the floor has a peak in the channel and the slopes extend down from the peak in different directions from the peak.

6. The display device of claim 2, wherein the floor has a peak at one end and a lowest point at the other end along a longitudinal direction of the channel.

7. The display device of claim 1, wherein a cross section of the lower part cut along a direction perpendicular to the longitudinal direction of the channel has one of a U-shape, an inverted triangle shape, and a quadrangular shape.

8. The display device of claim 1, wherein at least one of the pixel areas further comprises at least one of a hole injection layer and a hole transport layer between the first electrode and the emission layer.

9. The display device of claim 1, wherein each of the pixel areas further comprises:
a hole injection layer on the first electrode;
a primer layer on the hole injection layer; and
a hole transport layer on the primer layer.

10. The display device of claim 1, wherein the pixel further comprises at least one of an electron transport layer and an electron injection layer between the emission and the second electrode.

11. A manufacturing method of a display device, comprising:
forming a plurality of first electrodes on a substrate;
forming a pixel defining layer between the first electrodes;
forming an emission layer on the first electrode; and
forming a second electrode on the emission layer,
wherein the forming of a pixel defining layer includes forming a channel that is configured to allow a fluid material to flow between the first electrodes.

12. The manufacturing method of a display device of claim 11, wherein the forming of a pixel defining layer includes forming a pattern using a photoresist and a mask, and the mask has a channel forming unit and the channel forming unit is formed to change light transmission along a longitudinal direction.

13. The manufacturing method of a display device of claim 11, wherein the method further comprises coating at least one of a material for forming a hole injection layer and a material for forming a hole transport layer on the first electrode and the pixel defining layer before the forming of an emission layer and after the forming of the pixel defining layer.

14. The manufacturing method of a display device of claim 13, wherein the coating of at least one material for forming a hole injection layer and a material for forming a hole transport layer comprises using an ink printing method.

15. The manufacturing method of an organic light emitting display device of claim 11, further comprising using an ink printing method for the forming of an emission layer.

16. The display device of claim 2, wherein the slope in the channel floor is configured to move a liquid deposited on one part of the substrate to another part.

17. The display device of claim 1, wherein the floor of the channel is at the same level as or higher than the first electrode.
